(19) United States
(12) Patent Application Publication
(10) Pub. No.: US 2025/0102593 A1
(43) Pub. Date: Mar. 27, 2025

(54) JACOBIAN REGULARIZED POWER ELECTRONIC DEVICE MONITORING

(71) Applicant: STMicroelectronics International N.V., Geneva (CH)

(72) Inventors: Francesco Rundo, Gravina di Catania (IT); Michele Calabretta, Giarre (CT) (IT); Marco Maria Branciforte, Catania (IT); Concetto Spampinato, Catania (IT); Salvatore Coffa, Milano (IT)

(21) Appl. No.: 18/472,684

(22) Filed: Sep. 22, 2023

(51) Int. Cl. G01R 31/40; G06N 3/084

(52) U.S. Cl. CPC G01R 31/40; G06N 3/084

(57) ABSTRACT

A method of characterizing a parameter (e.g., threshold voltage) of a power electronic device using an artificial intelligence (AI) model includes sampling measured parameter values (e.g., voltage, current) of the power electronic device during operation and characterizing the parameter of the power electronic device using the AI model in inference mode with the measured parameter values as inputs. The AI model is trained using a joint loss function including a Jacobian regularization term. The Jacobian regularization term may depend on the norm of at least one Jacobian of a corresponding set of training inputs. A power electronics system configured to perform the method includes the power electronic device and a computing system with a processor and memory storing the AI model. The computing system may be a microcontroller. The system may also include an analog-to-digital converter (ADC) circuit, such as in the microcontroller.

### TECHNICAL FIELD

The present invention relates generally to power electronics, and, in particular embodiments, to methods and structures of characterizing parameters of power electronic devices during operation.

### BACKGROUND

Power electronics are used to control and convert electric power in electronic devices. Power electronic devices are used in all electronic applications ranging from power grids to personal computers, appliances to smart phones, and so on. Due to the prevalence of electronic devices, power electronic devices are highly important and are becoming even more important as more and more industries transition to electric power (e.g., the automotive industry, for example).

Over time, power devices may degrade causing device malfunctions and eventual inoperability. As a result, health monitoring of power electronic devices is important in order maintain device integrity and adapt to changes in device behavior over time as well as to allow replacement of power devices before a full breakdown. For example, accurate health monitoring of a power device may allow parameters to be gradually changed to compensate for gradual device degradation. Once the degradation progresses past a certain threshold, but before the power device stops functioning, the power device may be replaced.

Various properties of power devices may be measured in order to ascertain the health of the power device. For example, device resistance, current, voltage, at one or more regions of the power device may be measured. Other properties may also be monitored, such as response time, optical properties, acoustic properties, temperature, humidity, and others. Health monitoring measurements may be taken during operation and/or when the device is off, at regular intervals or during specific windows. Real-time health monitoring is desirable to allow an electronic system to adapt to changes in device health during operation, predict problems before they occur, and improve outcomes in the event of device malfunction.

Health monitoring of power electronic devices in modern electronic systems, such as automotive electronic systems, can be challenging for a number of reasons. It can be difficult to identify predictive markers of device degradation that are both accurate and measurable. Additionally, the correlation between measured values and device health may be complicated and not fully understood. Measurements of device properties such as resistance, current, and voltage during device operation can also be subject to high levels of noise, which may also be unpredictable. Additionally, health monitoring may need to be conducted often and with limited resources, such as locally using a microcontroller. Accurate measurements for health monitoring may be unattainable given the combination of device complexity, time constraints, and limited resources.

Therefore, health monitoring systems and techniques that are able to quickly and locally provide accurate health monitoring of power electronic devices during operation are desirable.

### SUMMARY

In accordance with an embodiment of the invention, a method of characterizing threshold voltage of a power electronic device using an artificial intelligence (AI) model includes sampling measured voltage and current values of the power electronic device at power-on, and characterizing the threshold voltage of the power electronic device using the AI model in inference mode with the measured voltage and current values as inputs. The AI model is trained using a joint loss function that includes a Jacobian regularization term to compensate for noise. Both the sampling and the characterization of the threshold voltage are performed by a microcontroller of the power electronic device.

In accordance with another embodiment of the invention. a method of training an artificial intelligence (AI) model to characterize a parameter of a power electronic device using voltage and current measured during operation of the power electronic device includes generating sets of simulated voltage and current values using a simulated power electronic device, injecting simulated noise into the sets of simulated voltage and current values to generate noisy sets of voltage and current values, and inputting the noisy sets of voltage and current values into the AI model in training mode as sets of training inputs to train the AI model using a joint loss function to generate a weighted tensor. The joint loss function includes a bare loss term and a Jacobian regularization term. The Jacobian regularization term is dependent on the norm of at least one Jacobian of a corresponding set of the training inputs. Each of the sets of simulated voltage and current values corresponding to a set of simulation parameters of the simulated power electronic device. The AI model is configured to be used in inference mode to characterize the parameter of the power electronic device using the weighted tensor with measured voltage and current values as inputs.

In accordance with still another embodiment of the invention, a power electronics system includes a power electronic device and a microcontroller including a processor and a non-transitory computer-readable memory storing a program that, when executed by the processor, causes the power electronics system to perform a method of characterizing a parameter of the power electronic device using an artificial intelligence (AI) model. The method includes sampling measured voltage and current values of the power electronic device at power-on, and characterizing the parameter of the power electronic device using the AI model in inference mode with the measured voltage and current values as inputs. The AI model is trained using a joint loss function including a Jacobian regularization term to compensate for noise.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a block diagram of an example power electronics system including a power electronic device and a computing system configured to characterize a parameter of the power electronic device using an artificial intelligence (AI) model trained using a joint loss function with a Jacobian regularization term in accordance with embodiments of the invention;

FIG. 2 illustrates a block diagram of an example training system including a simulated power electronics system with a simulated power electronic device where the training system is configured to train an AI model using a joint loss function with a Jacobian regularization term in accordance with embodiments of the invention;

FIG. 3 illustrates a block circuit diagram of an example conditioning circuit including one or more operational amplifiers and configured to condition raw parameter signals to be received by an analog-to-digital converter (ADC) circuit in accordance with embodiments of the invention;

FIG. 4 illustrates a block circuit diagram of an example conditioning subsystem including a conditioning circuit coupled to a power electronic device in accordance with embodiments of the invention;

FIG. 5 illustrates a circuit diagram of another example conditioning subsystem including a conditioning circuit coupled to a power electronic device in accordance with embodiments of the invention;

FIG. 6 illustrates a qualitative graph of measured parameters of a power electronic device showing drain current (I_{D}) as a function of drain-source voltage (V_{DS}) for various gate-source voltages (V_{GS}) in accordance with embodiments of the invention;

FIG. 7 illustrates example Jacobian regularization equations that include the Frobenius norm of the Jacobian and batch processing of training data in accordance with embodiments of the invention;

FIG. 8 illustrates an example method of characterizing a parameter of a power electronic device using an AI model in accordance with embodiments of the invention; and

FIG. 9 illustrates an example method of training an AI model to characterize a parameter of a power electronic device in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope. Unless specified otherwise, the expressions “around”, “approximately”, and “substantially” signify within 10%, and preferably within 5% of the given value or, such as in the case of substantially zero, less than 10% and preferably less than 5% of a comparable quantity.

One of the classic problems of power electronics (e.g., in the automotive field) is related to the health monitoring of both electronic power devices including both discrete and modular power devices. Identifying predictive markers indicating early device degradation have become the focus of an important effort in the automotive sector. One such predictive element of device degradation is the drift of device threshold voltage over time. For example, degradation processes at the gate oxide level may lead to a significant drift of the actual and real threshold voltage of the device. This can in turn lead to malfunctions at power up and eventually to final breakdown of the electronic power device (e.g., gate oxide breakdown to the extent that there is an electric short through the gate oxide).

In the specific case of an electronic power device including a metal-oxide-semiconductor field-effect transistor (MOSFET such as a silicon MOSFET, silicon carbide (SiC) MOSFET), the threshold voltage of the power MOS device drifts when degradation of the power MOS interface has started. This drift, which is a change over time (e.g., an increase or decrease in the value of the threshold voltage), is then an important marker that can be monitored to understand if degradation has started in the device. The threshold voltage is a key parameter in the trapping of oxide in the devices, which is a form of gate oxide degradation of the power MOS device. For this reason, the threshold voltage of the power MOS device may be useful for the health monitoring and predictive monitoring of the power MOST device.

It is not possible to measure the threshold voltage of an electronic power device directly. Consequently, retrieving the actual threshold voltage of an electronic power device is not trivial and often requires some combination of measurements and conventions to be applied to estimate the value of the threshold voltage. For instance, electrical measurements of the power electronic device (e.g., voltage and current measurements) may be subject to a high degree of signal noise (i.e., creating a low signal-to-noise ratio). Sources of the signal noise may include electronic noise caused by the electronic circuitry itself and analog-to-digital converter (ADC) conversion noise, as well as environmental noise (e.g., from the static environment of the electronic power device or from dynamic external factors). As a result, the noise may vary between devices, systems, and environments.

Conventional techniques for estimating the drift of the threshold voltage in electronic power devices do not have any prediction capabilities, noise compensation, or adaptability to different devices and environments. Further, conventional threshold voltage drift techniques capable of attaining the accuracy requirements of contemporary power electronics systems are too slow and computationally intensive to be locally implemented (e.g., embedded in a microcontroller, etc.).

The systems and methods described herein robustly characterize parameters of a power electronic device during operation using a locally hosted artificial intelligence (AI) model to provide real-time or near real-time health monitoring. In various embodiments, a method of characterizing a parameter (e.g., threshold voltage) of a power electronic device (e.g., a power Si device, a power SiC device) using an AI model (e.g., back propagation of a deep neural network) is provided. The method includes sampling measured parameter values (e.g., voltage, current, etc.) of the power electronic device during operation (e.g., at power-on) and characterizing the parameter of the power electronic device using the AI model (e.g., outputting an estimated parameter value) in inference mode with the measured parameter values as inputs.

A number of samples may be acquired from the power electronic device during operation. For example, the samples may be acquired in the linear region of the power electronic device during a transient period (e.g., while transitioning to the saturation region). The AI model is trained using a joint loss function including a Jacobian regularization term (e.g., to compensate for noise). For example, the Jacobian regularization term may depend on the norm (e.g., a matrix norm such as the Frobenius norm) of at least one Jacobian of a corresponding set of the training inputs. The joint loss function may also include additional terms, such as a bare loss function (e.g., quadratic loss, mean-squared error loss, etc.).

In various embodiments, a power electronics system configured to perform the method includes the power electronic device and a computing system with a processor and memory storing the AI model. For example, the memory (or another memory) may store a program causing the processor to perform the method. The computing system may include a microcontroller (e.g., a microcontroller unit (MCU)) containing the processor and the memory, which may have volatile memory (e.g., random access memory (RAM)) and non-volatile memory (e.g., flash memory). The power electronics system may also include an analog-to-digital converter (ADC), such implemented as a peripheral component of a microcontroller. Although the entire computing system may be implemented locally, such as in an embedded power electronics system (e.g., an automotive electronics system), one or more components of the computing system may also be remotely located relative to the power electronic device.

The switching speed of the power electronic device may be relatively high (such as on the order of milliseconds. For example, the acquisition speed of the number of samples may be fast enough to provide an output (e.g., the estimated threshold voltage) in real-time or near-real-time. For instance, the number of samples may be acquired within the switching speed of the power electronic device. Additionally, the use of an AI model in inference mode may advantageously reduce the computational cost of generating an output so that the results are obtained in real-time or close to real-time (e.g., 50 ms).

In various embodiments, the AI model is trained to characterize the parameter of a power electronic device by generating sets of simulated parameter values (e.g., voltage and current) using a simulated circuit including a simulated power electronic device. Each of the sets corresponding to a set of simulation parameters (e.g., device parameters, circuit parameters, electrical parameters, etc.) of the simulated circuit. For example, the characteristics of the simulated circuit may be defined and varied across a broad range power electronic devices and power electronics systems using the sets of simulation parameters, each corresponding to one or more sets of simulated parameter values.

Simulated noise is then injected into the sets of simulated parameter values to generate noisy sets of parameter values. In some cases, the type of simulated noise may be varied between different simulated parameters and noise may not be injected into some parameters. The noisy sets of parameter values are input into the AI model in training mode as sets of training inputs to train the AI model using a joint loss function including the Jacobian regularization term to generate a weighted tensor. The AI model is configured to be used in inference mode to characterize the parameter of the power electronic device using the weighted tensor with measured parameter values of the power electronic device as inputs.

The use of Jacobian regularization techniques may advantageously allow compensation of noise (such as electronic noise, ADC noise, environmental noise) while monitoring the health of the power device. For example, the Jacobian regularization term may be included in the loss function when the AI model is in training mode. In inference mode, real samples (including any noise) may then be input into the AI model and the output accounts for the noise because the Jacobian regularization term as included during training. Jacobian regularization techniques may have the advantage of being well-suited for the types of noise that may often be present in a power electronics system resulting in robust characterization of predictive parameters such as threshold voltage drift.

Various implementations may advantageously utilize threshold voltage drift as a predictive marker of device fault. The use of AI techniques may provide the advantage of facilitating accurate characterization of predictive parameters such as threshold voltage drift locally in an embedded system. Further, the characterization may be performed quickly, such as in real-time or near real-time. In many cases, the characterization may be performed using only simple acquisition of voltages and currents at power-on, which may also be an advantage over conventional techniques.

The performance of the AI model may be advantageously high, (e.g., about 96% and higher) due to the ability to train the AI model using thousands of configurations. The information provided by the AI techniques may also beneficially enable intelligent monitoring. For example, beyond simply determining the existence of degradation, the significance of the degradation to the current and future health of the power device may be determined. In some cases, the degradation may be rehabilitated using new parameter values, such as driving voltage, gate voltage, source voltage, etc.

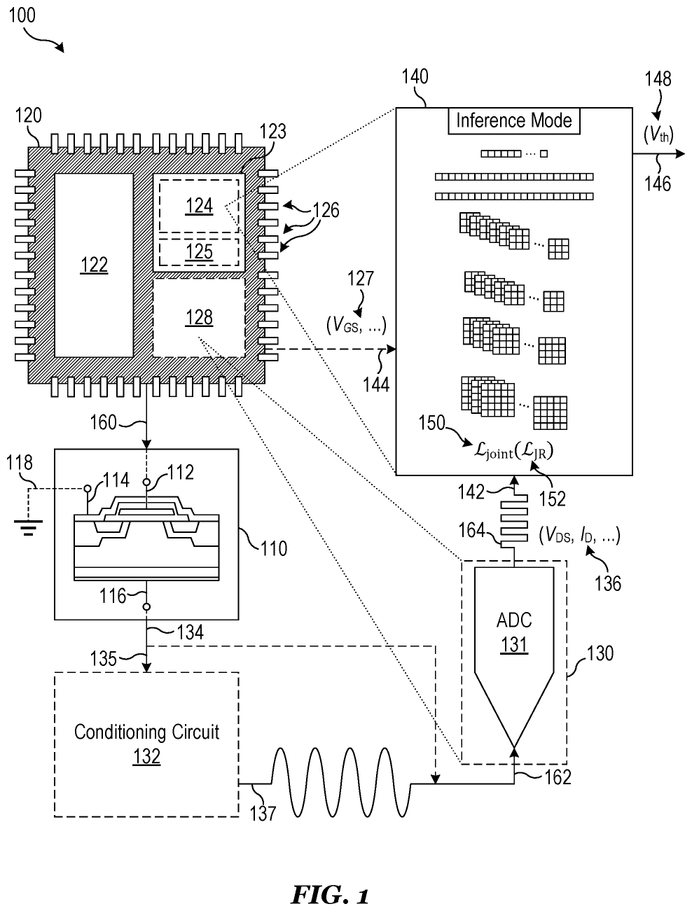

FIG. 1 illustrates a block diagram of an example power electronics system including a power electronic device and a computing system configured to characterize a parameter of the power electronic device using an artificial intelligence (AI) model trained using a joint loss function with a Jacobian regularization term in accordance with embodiments of the invention.

Referring to FIG. 1, a power electronics system 100 includes a power electronic device 110 and a computing system 120 that includes a processor 122 and a memory 123 storing an AI model 140. The power electronics system 100 is configured to perform a method of characterizing a parameter 148 of the power electronics device 110 (e.g., threshold voltage, such as the change in the threshold voltage over time, referred to as threshold voltage drift) using the AI model 140. Specifically, the computing system 120 (such as a microcontroller, for example) is configured to sample measured parameter values 136 of the power electronic device 110 (e.g., measured voltage and current values) and characterize the parameter 148 using the AI model 140 in inference mode. For example, the processor 122 may be configured to execute a program stored in the memory 123 (or elsewhere, such as any non-transitory computer-readable memory) that, when executed by the processor 122 causes the power electronics system 100 to perform the method of characterizing the parameter 148.

In various embodiments, the sampling is performed at device power-on, but sampling may also be performed on demand or on a schedule as additions or alternatives. The measured parameter values 136 are provided to the AI model 140 as inputs (i.e., measured AI model inputs 142) and the AI model 140 is configured to provide an output used to characterize the parameter 148 (e.g., an estimated parameter value 146, such as the value of the threshold voltage, for example). The AI model 140 is configured to be trained using a joint loss function 150 that includes a Jacobian regularization term 152 (e.g., in addition to one or more additional terms). The inclusion of the Jacobian regularization term 152 may have the advantage of enabling the AI model 140 to compensate for noise that may be present in the power electronics system 100, such as when sampling, transferring, or processing the measured parameter values 136.

The power electronic device 110 is electrically coupled to the computing system 120. The power electronic device 110 is configured to control or convert electric power within the power electronics system 100. The computing system 120 sends a control signal 160 to the power electronic device 110 causing the power electronic device 110 perform a desired function. For example, the control signal 160 may be configured to allow or disallow current to flow through the power electronic device 110 as well as control various dynamics of the current flow.

During operation of the power electronic device 110 and in response to receiving the control signal 160, various measured parameter signals 134 may be generated by the power electronic device 110. The measured parameter signals 134 are analog signals at this stage and are supplied as analog signals 162 to an ADC 131 (or multiple signals to multiple ADCs). For example, the ADC 131 may be included as part of an ADC circuit 130 that includes multiple ADCs (possibly also in addition to various other components). The ADC circuit 130 is configured to receive the analog signals 162 (the measured parameter signals 134, such as voltage and current measurements) from the power electronic device 100, convert the analog signals 162 to digital signals 164 (e.g., voltage and current values), and output the digital signals 164 as the measured parameter values 136 to the computing system 120 (e.g., the processor 122) for use as the measured AI model inputs 142 to the AI model 140.

The ADC circuit 130 may be implemented as a standalone circuit in the power electronics system 100, integrated on the same substrate or in the same package as the power electronic device 110, or included in the computing system 120. In the specific case were the computing system 120 is implemented as a microcontroller in the power electronics system 100, one or more of the ADCs in the ADC circuit 130 may be included as part of optional peripherals 128 of the microcontroller.

The power electronics system 100 may be any system of electrically coupled components configured to control and convert electrical power. The power electronics system 100 may include any number of additional devices in addition to the power electronic device 110. In various embodiments, the power electronics system 100 is an embedded system in an electrically-powered device. For example, the power electronics system 100 may be an embedded system in a vehicle such as an automobile, watercraft, aircraft, etc., an embedded system in a computing system such as a personal computer, laptop, tablet, smartphone, etc., an embedded system in an appliance such as a refrigerator, dish washer, clothes washer, oven, etc., or an embedded system in any other device that internally controls or converts electric power.

The power electronic device 110 may be an active device, such as a transistor, rectifier, thyristor, gated diode, and the like. In various embodiments, the power electronic device 110 is a power transistor and is a field-effect transistor (FET) in some embodiments. Other types of transistors are also possible, such as a bipolar junction transistor (BJT), for example. In one embodiment, the power electronic device 110 is a power metal-oxide-semiconductor field-effect transistor (MOSFET), such as a power silicon MOSFET. The power electronic device 110 may be fabricated using various materials. In some embodiments, the power electronic device 110 is a power (Si) device. In other embodiments, the power electronic device 110 is a power silicon carbide (SiC) device. Further, the power electronic device 110 may be an n-type or p-type device, an integrated or discrete device, and may be an array of identical, similar, or even different devices.

The power electronic device 110 includes a control input 112 and one or more input/output (I/O) nodes. For example, the power electronic device 110 may include a first I/O node 114 and a second I/O node 116 as shown. The control input 112 may be configured to control the flow of current between the first I/O node 114 and the second I/O node 116, for example. Depending on the type of device, the control input 112 and the I/O nodes may be referred to with specific labels associated with the device. For example, when the power electronic device 110 is a power FET (e.g., a power MOSFET), the control input 112 may be referred to as a gate, the first I/O node 114 may be referred to as a source, and the second I/O node 116 may be referred to as a drain. Of course, other labels may also be used, such as base-collector-emitter (BJT), gate-collector-emitter (insulated-gate bipolar transistor or IGBT), gate-anode-cathode (thyristor), and so on.

In the specific example of a power MOSFET (as illustrated), the control signal 160 may be coupled to the control input 112 (gate) of the power electronic device 110 while the measured parameter signals 134 may be obtained from the second I/O node 116 (drain). In this configuration, the first I/O node 114 (source) may be coupled to a reference potential 118 (e.g., a ground potential).

In some applications, such as when the power electronic device 110 is a switching device that turns “on” and “off” (e.g., to allow or disallow current to flow), the parameter 148 of the power electronic device 110 is the threshold voltage Vₜₕ of the power electronic device 110. The measured parameter values 136 may be related to the threshold voltage Vₜₕ, such as the drain-source voltage V_{DS} and the drain current ID and the power electronic device 110. Other additional parameter values may also be input into the AI model 140, such as the gate-source voltage V_{GS}, for example.

The threshold voltage drift may be related to the degree of degradation of the power electronic device 110. For example, the threshold voltage of the power electronic device 110 may drift during use as the gate-source voltage V_{GS} is applied to switch the power electronic device 110 on and off. For example, when V_{GS} is applied, the threshold voltage goes up and down (a so-called hysteretic trend). When V_{GS} is positive there is a positive threshold voltage drift (positive bias temperature instability or positive BTI) and there is a negative BTI when V_{GS} is negative. At low frequency, the positive and the negative BTI tend to cancel one another out.

However, when V_{GS} is applied more quickly, such as at 150 kHz, 200 kHz, etc., the asymmetry between the positive and negative BTI may be exposed and a net threshold drift may appear. For example, dynamic switching may result in a net positive BTI even though the threshold voltage is drifting in both directions during each cycle. Because the dynamic BTI occurs at higher switching frequencies, this type of BTI may be referred to as alternating current (AC) BTI.

The threshold voltage Vₜₕ may affect device performance. For example, a positive Vₜₕ drift increases the drain-source resistance when the device is turned on (RDS,on) which, consequently, decreases the current level for a given driving gate voltage. The mechanism that causes Vₜₕ drift (e.g., charging and discharging of oxide trap) may vary from device to device and may be impossible to prevent. Moreover, for multi-chip devices, nonuniform degradation of Vₜₕ among chips may lead to uneven switching (for example, a chip with a lower Vₜₕ tends to switch on before other chips and the gap widens over time) causing current and temperature imbalance. In cases where the Vₜₕ drift is negative, the negative variations could cause parasitic turn-on at high drain current, with catastrophic consequences.

The computing system 120 may be any suitable type of computing system that includes a processor and a memory. For example, the computing system 120 may be implemented as a microcontroller (MCU) in an embedded power electronics system. Alternatively, the computing system 120 may be a personal computer, laptop computer, tablet computer, smart phone, etc. The processor 122 may be any suitable processor, such as the processor of a microcontroller, a general purpose processor, a microprocessor, a field-programmable gate array (FPGA), an application-specific integrated circuit (ASIC), and others.

The computing system 120 may include various types of memory in the memory 123. As shown, the memory 123 may include a non-volatile memory 124 and a volatile memory 125. The volatile memory 125 may be high-speed memory such as random access memory (RAM) while the non-volatile memory 124 may be persistent memory, such as flash memory. In various embodiments, the AI model 140 and the program causing the power electronics system 100 to characterize the parameter 148 of the power electronic device 110 may be stored in the non-volatile memory 124 of the computing system 120. The computing system 120 may also include optional peripherals 128, such as one or more ADCs, as well as various other I/O peripherals. Various terminals 126 may be included in the computing system 120 for input/output and power. For example, the computing system 120 may include general purpose input-output (GPIO) pins, which may be used to provide the control signal 160 to the power electronic device 110 and to receive the analog signals 162 when an ADC of the computing system 120 is used.

The ADC circuit 130 is configured to receive one or more analog signals 162 corresponding to measurable parameters of the power electronic device 110 and convert the analog signals 162 to the digital signals 164. Specifically, the digital signals 164 represent the amplitude of the analog signals 162 at an instance in time using a number of bits (e.g., any suitable number, as low as two for on-off behavior and increasing for more accurate resolution of the analog signals, such as 12 bits, for example). The samples of the measured parameter values 136 (e.g., the drain-source voltage VDs, drain current ID, etc.) are collected from the power electronic device 110 by the ADC circuit 130.

The AI model 140 may be any suitable model configured to accept a plurality of inputs (i.e., measured AI model inputs 142) and provide an output that is used to characterize the parameter 148 of the power electronic device 110. For example, the AI model 140 may be implemented as a neural network, such as a deep neural network (i.e., an artificial neural network that has multiple layers of artificial neurons between the input and output layers). The computing system 120 stores the AI model 140 in the memory 123. For example, a neural network backbone (e.g., the framework of the AI model 140, such as the feature extraction portions) may be stored in the memory 123. The ADC circuit 130 is configured to collect the variables that are then fed into the AI model 140.

In the specific example of sampling voltage and current values of the power electronic device 110 implemented as a power FET, the measured AI model inputs 142 of the AI model 140 are measurable conductance characteristics of the power electronic device 110. For instance, a conductance profile may be collected by sampling the drain current I_{D} and the drain-source voltage V_{DS} of the device. This conductance profile may represent the starting behavior of the device (e.g., when a gate-source voltage V_{GS} is applied and the device turns on). In this way, the characterization of parameter 148 (such as the threshold voltage) may be obtained through simple acquisition of voltages and currents at power-on. The evolution of the parameter 148 may be monitored over time and each time the device is used.

Any suitable number of samples may be taken. The statistical accuracy of the characterization of the parameter 148 may improve as the number of samples is increased. However, the complexity and the time required to characterize the parameter 148 may also increase. For example, the number of samples may be 30 samples, 60 samples, and so on. In some specific applications, the choice of 30 samples may represent a good tradeoff between performance and computational cost of the AI model 140. In some cases, there may exist a number of samples that represents a cutoff where there is no significant performance gain is obtained, but computational cost continues to rise. This number may be 30 samples in some applications (e.g., a power MOSFET using a deep neural network), but the specific cutoff number of samples will depend on the specifics of a given application.

The AI model 140 (e.g., the neural network) works in inference mode to generate an output (such as the estimated parameter value 146). Training may be performed separately offline on a server, (e.g., because training is very computationally intensive). The trained AI model 140 is hosted as a framework in the computing system 120 (e.g., a microcontroller or MCU). The computing system 120 may retrieve input information (the measured AI model inputs 142) for the AI model 140 from the ADC circuit 130 (e.g., of the MCU). During inference mode, the AI model 140 operates in a feedforward manner in the computing system 120 with a static tensor (a weighted tensor generated in training mode) that acts as the rule set of the knowledge of the AI model 140. Various algorithms may be used to train the AI model 140 (i.e., generate the weighted tensor), such as backpropagation algorithms including modified backpropagation algorithms utilizing the Levenberg-Marquardt algorithm.

In some cases, additional inputs other than measured inputs may also be provided to the AI model 140. For example, direct AI model inputs 144 may be provided to the AI model 140 that include information sent directly to the AI model 140 by the computing system 120. One possibility for the direct AI model inputs 144 are direct parameter values 127, such as gate-source voltage V_{GS}. That is, the inputs to the AI model 140 may include the gate-source voltage of the power electronic device 110. For example, the computing system 120 is already providing the control signal 160 to the power electronic device 110 and therefore has the voltage value of the control signal 160 (nominally or in fact). Thus, the control signal 160 (V_{GS} for power FETs, for example) can be provided directly to the AI model 140 as shown.

The use of the AI model 140 stored in the memory 123 of the computing system 120 may advantageously allow the characterization of the parameter 148 to be performed locally (e.g., in a microcontroller of an embedded system) and in real-time or near real time. For example, the estimated parameter value 146 (such as the threshold voltage) may be output by the AI model 140 within about 100 ms of powering on the power electronic device 110. Additionally, due to the relationship of the threshold voltage drift to the health of the power electronic device 110, the drift of the threshold voltage of the power electronic device 110 can be characterized as a predictive marker of device degradation. Further, any device degradation may be rehabilitated using new parameter values selected according to the characterization. The new parameter values may include one or more of driving voltage, gate voltage, or source voltage, as examples.

An optional conditioning circuit 132 may be coupled between the power electronic device 110 and the ADC circuit 130. The conditioning circuit 132 may be configured to condition raw parameter signals 135 (e.g., raw analog voltage and current signals) to generate conditioned parameter signals 137 (the analog signals 162) received by the ADC circuit 130. The optional conditioning circuit 132 may include various components, such as operational amplifiers. The optional conditioning circuit 132 may be desirable because the ADC circuit 130 may not be directly wired to the terminal of the power electronic device 110. The optional conditioning circuit 132 may be configured to act as a setup circuit so that the raw voltage and current values can be normalized into the range of the ADC(s) in the ADC circuit 130.

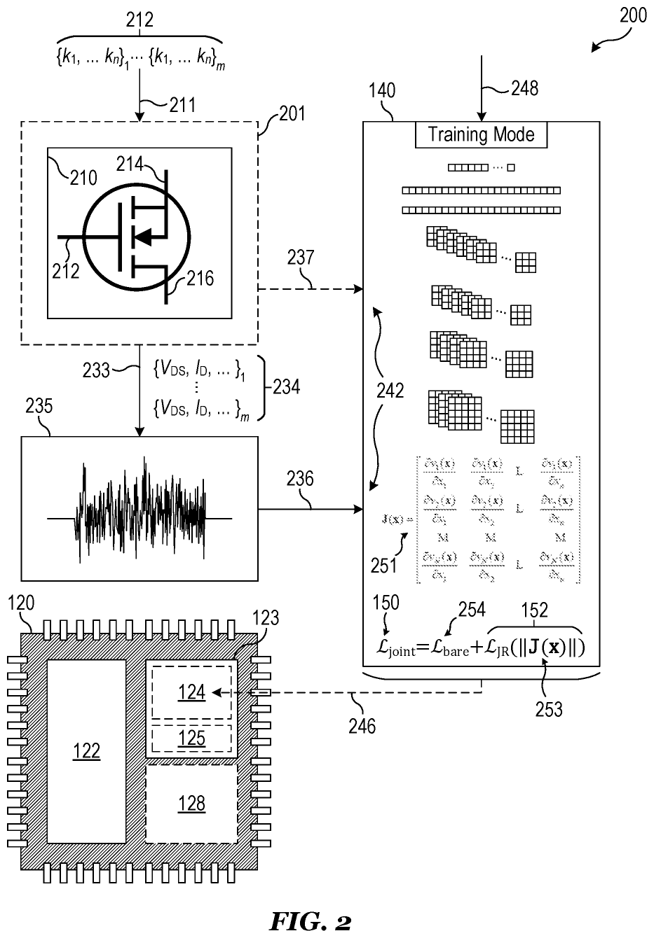

FIG. 2 illustrates a block diagram of an example training system including a simulated power electronics system with a simulated power electronic device where the training system is configured to train an AI model using a joint loss function with a Jacobian regularization term in accordance with embodiments of the invention. The training system of FIG. 2 may be used to train AI models stored in computing systems of power electronics systems described herein, such as the power electronics system of FIG. 1, for example. Similarly labeled elements may be as previously described.

Referring to FIG. 2, a training system 200 includes a simulated power electronics system 201 that includes a simulated power electronic device 210 and an AI model 140. It should be noted that here and in the following a convention has been adopted for brevity and clarity wherein many elements adhering to the pattern [x10] where ‘x’ is the figure number may be related implementations of a power electronic device in various embodiments. For example, the simulated power electronic device 210 may be similar to the power electronic device 110, except as otherwise stated, (but the simulated power electronic device 210 is a simulated device). An analogous convention has also been adopted for other elements as made clear by the use of similar terms in conjunction with the aforementioned numbering system.

The training system 200 is configured to perform a method of training the AI model 140 to characterize a parameter 248 (e.g., threshold voltage) of a power electronic device (i.e. corresponding to the simulated power electronic device 210) using parameters (e.g., voltage and current) measured during operation of the power electronic device. The training system 200 may be hosted in any suitable computing system that includes a processor and memory to store the AI model 140 and a program that, when executed by the processor of the training system 200 causes the training system 200 to perform the method of training the AI model 140.

The simulated power electronics system 201 includes the simulated power electronic device 210, which is a simulated circuit of an actual electronic device of a power electronics system (which as power electronic device 110 of the power electronics system 100, for example). For example, the simulated power electronic device 210 includes a simulated control input 212 (e.g., a gate) and one or more simulated I/O nodes, such as the first simulated I/O node 214 (e.g., a source) and the second simulated I/O node 216 (e.g., a drain). The simulated power electronics system 201 is configured to generate sets 234 of simulated parameter values 233 (e.g., simulated voltage and current values) using simulated power electronic device 210. Accordingly, the simulated power electronic device 210 is configured to simulate the behavior of a corresponding power electronic device in a corresponding power electronics system so that trained AI model 140 will accurately characterize the parameter 248 for the system and device in inference mode.

Sets 213 of simulation parameters 211 are input into the simulated power electronics system 201 to define the specific parameters of the simulated power electronics system 201 and the simulated power electronic device 210. For example, each set 213 may correspond with a particular configuration of the simulated power electronic device 210 and of the simulated power electronics system 201 itself. The sets 213 may be chosen to cover a range of possibilities so that the trained AI model 140 is capable of providing accurate characterization of a broad range of configurations, operating parameters, and operating environments.

Each set 213 of simulation parameters 211 may include various adjustable parameters. Some parameters may remain fixed, the identity of which may be related to the number and type of power electronics systems and power electronic devices that the trained AI model 140 can characterize. Some possible simulation parameters 211 include number of devices (e.g., for arrays of devices such as if the simulated power electronic device 210 is an array of power electronic devices), device dimensions (including oxide thickness, channel length and width, etc.), material types and characteristics (e.g., Si, SiC, etc.), gate-source voltage (e.g., as a function of time), as well as many others.

The simulated power electronics system 201 generates the sets 234 of simulated parameter values 233 as outputs. The simulated parameter values 233 are configured to correspond with the measured parameter values from an actual power electronic device of a power electronics system, such as the measured parameter values 136 from the power electronic device 110 of the power electronics system 100, for example. Accordingly, each set 234 of the simulated parameter values 233 may include parameters such as V_{DS} and I_{D}, as well as others.

The training system 200 is further configured to inject simulated noise 235 into the sets 234 of the simulated parameter values 233 (e.g., simulated voltage and current values) to generate noisy sets of parameter values 236 (e.g., noisy sets of voltage and current values). Various types of noise may be included in the simulated noise 235. The type and range of noise may be different for different simulated parameter values 233 (relating to the actual sources of noise in the simulated power electronics system 201, for example). The simulated noise 235 may be various types or combinations of noise, such as Gaussian noise, random noise, pink noise, etc.

As mentioned in the preceding, other inputs (e.g., optional direct parameter values 237) may also be provided to the AI model 140. In some cases, noise may not be added to these inputs (e.g., if the values are not measured or are otherwise fixed or controlled). One possible example of an input to which noise may not be added is control voltage, such as gate-source voltage Vos. In this case, the control voltage may be provided directly as an input to the AI model 140. Alternatively, the nominal (or set) value of the control voltage may include noise or may not be an accurate enough representation of the actual voltage and the control voltage may be a measured parameter value that is included in the simulated parameter values 233 (and to which appropriate noise may be added).

The AI model 140 is configured to receive the noisy sets of parameter values 236 and the optional direct parameter values 237 as training inputs 242 (i.e., sets of training inputs corresponding to one or more sets 233 of simulated parameter values 233 and optional direct parameter values 237. That is, the training system 200 is configured to input the noisy sets of parameter values 236 (e.g., noisy sets of voltage and current values) into the AI model 140 in training mode as the sets of training inputs 242 to train the AI model 140. The training uses a joint loss function 150 that includes a bare loss term 254 and a Jacobian regularization term 152 to generate a weighted tensor 246. The weighted tensor 246 is then stored in memory 123 (e.g., non-volatile memory 124) of a computing system 120.

The Jacobian regularization term 152 is dependent on the norm 253 of at least one Jacobian 251 of a corresponding set of the training inputs. The AI model 140 is configured to be used in inference mode to characterize the parameter 248 of the power electronic device corresponding to the simulated power electronic device 210 using the weighted tensor 246 with the noisy sets of parameter values 236 (and, optionally, the optional direct parameter values 237) as inputs.

The bare loss term may be a function of the training inputs 242, training outputs (the result of processing the training inputs with the current weights), and the parameter 248 of the power electronic device (the known or calculated value of the parameter 248 for a given set of training inputs 242). The Jacobian regularization term 152 may be proportional to the summation of one or more functions of the norm 253 of the Jacobian 251 of a corresponding set of the training inputs 242. For example, each of the one or more functions may be the square of the Frobenius norm of the Jacobian 251.

The training mode of the AI model 140 may be configured to perform a backpropagation training algorithm to generate the weighted tensor 246. Backpropagation algorithms generate a set of outputs at an output layer for a given set of inputs into an input layer using current weights. Backpropagation algorithms then work backwards from the output layer back to the input layer to update the values of the weighted tensor using a loss function (here, the joint loss function 150), the training inputs 242 and the generated outputs. Once the error between the generated outputs and the training outputs across the entire data set falls within a desired accuracy, the weighted tensor 246 is output to be stored in the memory of actual power electronics systems. Various types of backpropagation algorithms may be used, such as backpropagation using steepest descent or modified backpropagation algorithms like Levenberg-Marquardt (LM) backpropagation (LM backpropagation is a subset of backpropagation algorithms).

The training inputs 242 may be processed in batches. For example, batches may be subsets of the entire set of training data. Rather than backpropagate for each individual set of training inputs 242, batch processing may only backpropagate (i.e., update the values of the weighted tensor 246) for each batch. The joint loss function 150 may then be dependent on the full batch of input and output values (multiple corresponding sets of each).

When the training system 200 is configured to process the training data in batches, the AI model 140 may be configured to input the noisy sets of parameter values 236 into the AI model 140 by repeating the steps of inputting a batch of the noisy sets of parameter values 236, processing the batch without updating internal parameters (i.e. the weighted tensor 246) of the AI model 140, and updating the internal parameters of the AI model after processing the batch (i.e. to process all of the batches across the data set). For example, the joint loss function 150 may be calculated for each batch by summing the norms of the Jacobian for each noisy set of voltage and current values of the batch and dividing by the batch size.

In summary, the processing pipeline of the methods of training and characterization is based on AI techniques with regularization of the Jacobian of the gradient of the inputs. A possible advantage is that the AI model is designed to compensate for the inevitable measurement and conversion noises present in the system and may be tailored to compensate for specific system environments (e.g., power electronics systems that include a microcontroller performing the method of characterization). Additionally, the methods may have the benefit of providing a robust characterization in real-time or near real-time, but with lower required computing power (so that characterization and device monitoring can be performed locally in an embedded system, using a microcontroller, for example.

The backbone of the AI model (e.g., a neural network) can be trained using backpropagation algorithms that are modified with the Jacobian regularization to learn the correlation between the samples provided as input and the real threshold voltage of the power electronic device. The specific choice of algorithms may be based on a variety of factors, such as the speed in inference mode, computational cost, and performance tradeoffs. As one specific example, LM backpropagation may allow high performance and fast calculation using several approximations in the second derivative (e.g., to the Jacobian matrix and the Hessian matrix) and in the steps of updating the weights during training. This may be useful, for example, to reduce the computational cost for fully connected networks. Therefore, for embedded applications, LM backpropagation may be advantageous over classical algorithms such as gradient descent backpropagation, and so on. However, in other cases, features of LM backpropagation (such as the approximations) may not be viable and other algorithms may be used.

The training data is retrieved through simulating using the simulated power electronics system 201 and the simulated power electronic device 210. The simulated power electronics system 201 may include various simulated circuits, such as the simulated power electronic device 210 (e.g., a simulated power MOSFET circuit), a simulated ADC circuit, simulated control signal (e.g., simulated gate-source voltage V_{GS}), and simulated elements to recreate the parameters of different power electronic devices that will be within the capabilities of the AI model 140 to accurately characterize.

The training system 200 may be any computing system, and may have considerable computing power compared to the power electronics systems (e.g., one or more servers compared to a microcontroller, for example). For this reason, a large amount of training data may be collected (e.g., thousands and thousands of simulated power electronic devices along with the associated simulated parameters, such as threshold voltages). In this way, the AI model 140 is trained to accurately characterize the parameter even in the presence of environmental and systemic noise as well as for different systems and device configurations.

As shown, the Jacobian 251 is a matrix of the partial derivatives of the outputs (v) with respect to the inputs (x). The Jacobian 251 is a two-dimensional mathematical structure. In the specific case where the output is the voltage and the inputs are the drain current I_{D}, the drain-source voltage V_{DS}, and the gate-source voltage V_{GS}, there are three columns of the Jacobian 251 (because there are three inputs). The Jacobian 251 is two dimensional and can be made into a scalar using an operation called normalization (the “norm”, shown as the norm 253), which may be any suitable normalization. In various embodiments, the norm 253 is Frobenius normalization.

The Jacobian 251 may be calculated (or approximated as the case may be) as part of the backpropagation algorithm during training. When this is the case, the additional Jacobian regularization term 152 is simply making an additional use of a matrix that is already calculated as part of the training algorithm. This may have the advantage of minimizing the increased computational cost of the training the AI model 140 compared to conventional methods (i.e. without an additional Jacobian regularization term).

The loss function is the function that associates the error of the AI model 140 with a number. For example, the error can be thought of as the distance between the actual output for a given set of inputs from the desired, known, or calculated output for the set of inputs. Conventional methods use a loss function that does not include the Jacobian regularization term 152, shown as the bare loss term 254. Including the Jacobian regularization term 152 with the bare loss term 254 forms a joint loss function 150. Bare (basic) loss terms include terms such as quadratic loss, entropy loss, cross-entropy order loss, means-squared error loss, and the like. Therefore, conventional methods may work with different types of bare loss functions, but do not include a Jacobian regularization term.

Including the Jacobian regularization term 152 may advantageously allow the AI model 140 to accurately characterize a parameter of a power electronic device in a power electronics system even when the oscillation (noise) on one or more of the input variables (measured parameters) is very high. The Jacobian regularization term 152 causes the oscillations (corresponding with noise as opposed to signal) to become a penalization of the loss allowing the AI model 140 to be more robust to noisy input data. For example, whereas the overall goal of the training algorithm is to iteratively reduce the loss function, noisy data will increase the loss function because of the Jacobian regularization term 152 and the AI model 140 will learn to disregard the oscillations as useless.

In this way, the additional processing of the inputs using the simulated noise 235 and the joint loss function 150 with the Jacobian regularization term 152 may advantageously enable the AI model 140 to recognize noise that is present in the input (noise that it would not otherwise recognize) and then understand that the output should not be affected by this noise. Specifically, if the Jacobian regularization term 152 is not in place during the training (the conventional bare loss function), then noise may undesirably cause erroneous outputs because the noise is treated as a normal input during the performance of the AI model 140 in a real power electronics system. Rather, the additional Jacobian regularization term 152 may provide the benefit of allowing the same (accurate) output to be produced even when noise is present.

FIG. 3 illustrates a block circuit diagram of an example conditioning circuit including one or more operational amplifiers and configured to condition raw parameter signals to be received by an analog-to-digital converter (ADC) circuit in accordance with embodiments of the invention.

Referring to FIG. 3, a conditioning circuit 332 includes a plurality of operational amplifiers 360 with inputs coupled one or more raw inputs 335 and an output coupled to a conditioned output of one or more conditioned outputs 337. The conditioning circuit 332 may include a plurality of operational amplifiers 360, as shown, where the output of each operational amplifier 361 is coupled to a respective conditioned output of the conditioned outputs 337.

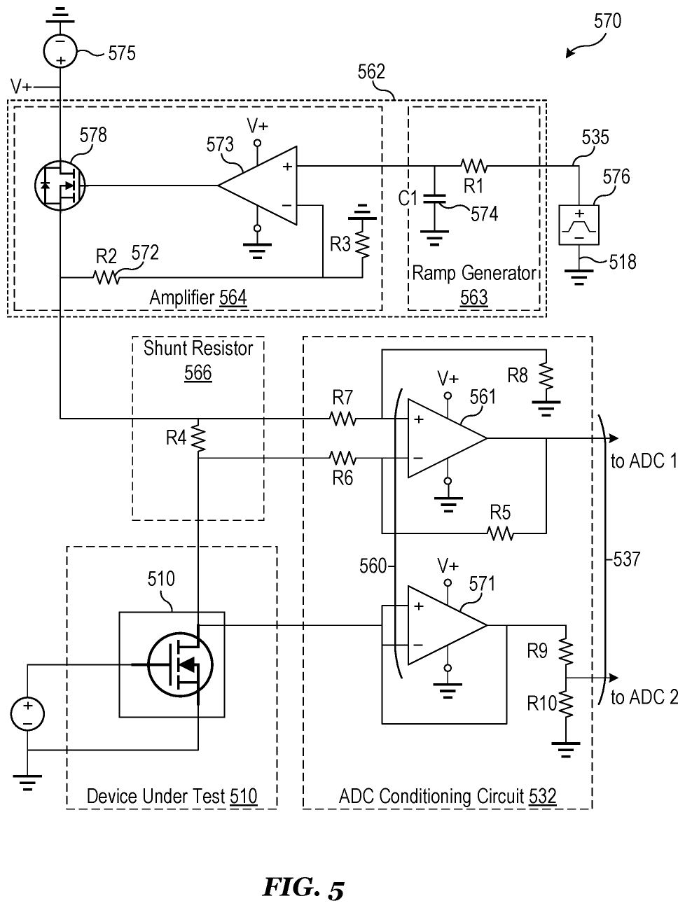

Of course, the conditioning circuit 332 may be implemented in more than one way. This configuration is a conceptual-level diagram that uses operational amplifiers to condition raw input signals. The conditioning circuit 332 may include various other components, one of example of which is shown in FIG. 5. The conditioning circuit 332 is configured to preprocess the measured parameters (e.g., voltage and the current) of the power electronic device to translate them into the range of one or more ADCs. For this reason, the conditioning circuit 332 is configured to perform a type of normalization on the raw signals. The implementation details of the signal normalization itself may be based on the specifics of a given ADC (or a microcontroller that includes the ADC, for example).

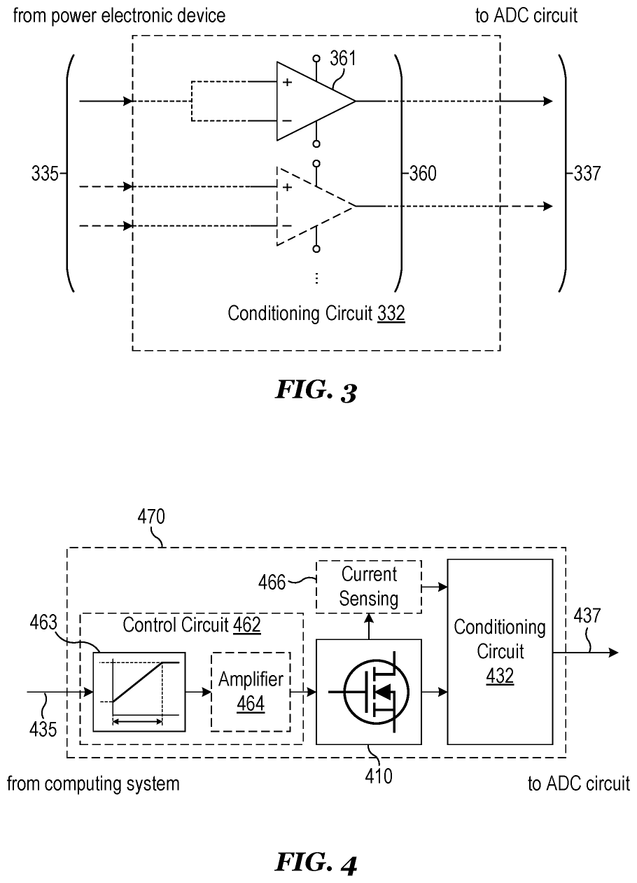

FIG. 4 illustrates a block circuit diagram of an example conditioning subsystem including a conditioning circuit coupled to a power electronic device in accordance with embodiments of the invention.

Referring to FIG. 4, a conditioning subsystem 470 includes a power electronic device 410 and a conditioning circuit 432. The conditioning subsystem 470 is configured to receive a control signal 435 and output one or more conditioned outputs 437 (e.g., to an ADC circuit). The conditioning subsystem 470 may include a control circuit 462 that includes a control signal generator circuit 463 and an amplifier 464 (as shown). For example, the control signal generator circuit 463 may be a voltage ramp generator and the amplifier 464 may be configured to amplify the ramped voltage to a desired level.

The conditioning circuit 432 is shown as a basic circuit block with two inputs (e.g., current and voltage) and an output to the ADC circuit of a power electronics system (e.g., included in an MCU). The power electronic device 410 may be coupled to the conditioning circuit 432 directly (e.g., in the case of measuring a voltage of the power electronic device 410) or through additional circuitry. For example, a current sensing circuit 466 is optionally included between the power electronic device 410 and the conditioning circuit 432 that allows a current value of the power electronic device 410 to be sampled and provided to the conditioning circuit 432.

FIG. 5 illustrates a circuit diagram of another example conditioning subsystem including a conditioning circuit coupled to a power electronic device in accordance with embodiments of the invention.

Referring to FIG. 5, a conditioning subsystem 570 includes a power electronic device 510 (the device under test or DUT) coupled between a control circuit 562 and a conditioning circuit 532, as well as various other electronic components such as resistors 572, capacitors 574, and ground nodes 518. In this specific example, the power electronic device 510 is a power MOSFET device, the source is coupled to a ground potential and the drain is coupled to both a current sensing circuit 566 (which is implemented as a shunt resistor R4, and which may have a relatively low resistance value such as 20 mΩ) and the conditioning circuit 532.

The conditioning circuit 532 includes a plurality of operational amplifiers 560 that includes a first operational amplifier 561 and a second operational amplifier 571. The conditioning circuit 532 is configured to receive the drain current I_{D} from the current sensing circuit 566 at the first operational amplifier 561 and receive the drain-source voltage V_{DS} at the second operational amplifier 571 from the direct connection to the power electronic device 510. In particular, the current sensing circuit 566 is coupled across the inputs of the first operational amplifier 561 through respective resistors (R6 and R7), which may be larger than R4, such as 4 kΩ. The plurality of operational amplifiers 560 are connected to a ground potential and a positive voltage V+ for power.

The output of the first operational amplifier 561 is configured to be coupled to a first ADC and is coupled to the negative input of the first operational amplifier 561 and the positive input of the first operational amplifier 561 is coupled to a ground potential through respective resistors R5 and R8, which may be relatively large (e.g., 200 kΩ). In contrast, both inputs of the second operational amplifier 571 are coupled to the output of the second operational amplifier 571 and the output is configured to be coupled to a second ADC using a voltage divider including resistors R9 and R10, which may have different resistance values, such as 30 kΩ and 10 kΩ, respectively.

The control circuit 562 includes a control signal generator circuit 563 (here, a ramp generator) and an amplifier 564. The ramp generator is configured to control the transient voltage, such as by causing a certain voltage curve, such as a linear curve. In this specific implementation, the combination of the resistor R1 (e.g., 24 kΩ) and the capacitor C1 (e.g., 10 μF) cause the voltage output to the amplifier 564 to be a linear voltage curve that reaches a constant maximum value.

The amplifier 564 includes a third operational amplifier 573, again powered by a positive voltage V+, with a positive input coupled to the control signal generator circuit 563 and a negative input coupled to a ground potential through a resistor R3, which may be relatively small (e.g., 20 kΩ). The output of the third operational amplifier 573 is coupled to the control input of an amplifying element 578 (such as the gate of a MOSFET, as shown). An input of the amplifying element 578 is coupled to a power source (such as the positive voltage V+) while the output of the amplifying element 578 is coupled to the current sensing circuit 566. The output is coupled to the negative input of the third operational amplifier 573 through a resistor R2 (e.g., 200 kΩ).

The conditioning subsystem 570 may correspond to a conditioning subsystem 570 of an actual power electronics system. Additionally, the conditioning subsystem 570 may also be part of a simulated power electronics system (as illustrated). Various simulated components such as voltage sources 575 and a pulse generator 576 may be included to simulate the behavior of components like processors, power supplies, and the like. Additionally, one or more of the resistors shown may be approximate resistances of other components in an actual power electronics system. The values of the resistances, capacitances, voltages, transient waveforms, etc. may be varied as parameters to approximate a wide variety of power electronics systems, for example.

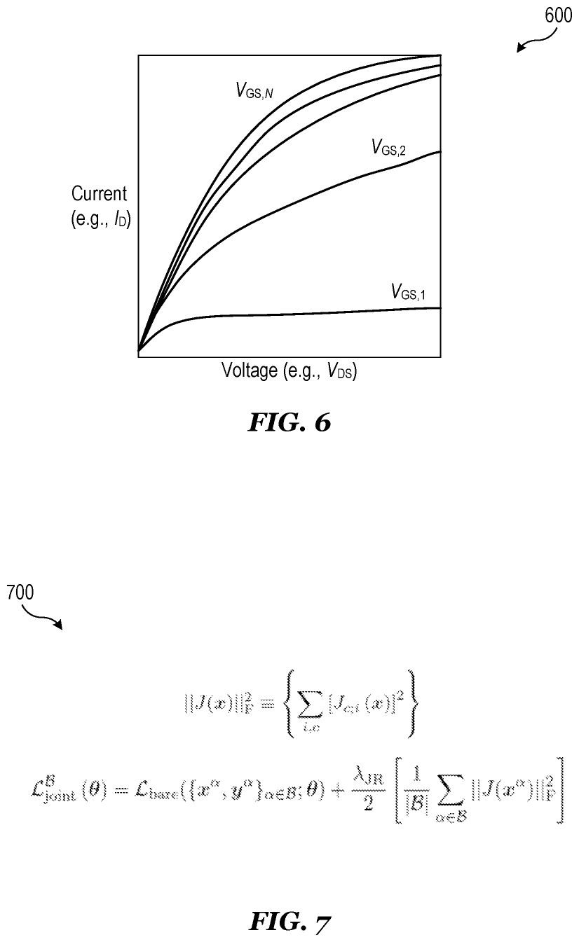

FIG. 6 illustrates a qualitative graph 600 of measured parameters of a power electronic device (here, a power FET) showing drain current (I_{D}) as a function of drain-source voltage (V_{DS}) for various gate-source voltages (V_{GS}) in accordance with embodiments of the invention. Once V_{GS} is greater than the short voltage, the device switches from a linear region (i.e., the left region of the graph) to a saturation region (i.e., the device becomes a short). In a closed loop, all the current from the drain will flow to the source, which is the behavior of the power FET.

FIG. 7 illustrates example Jacobian regularization equations that include the Frobenius norm of the Jacobian and batch processing of training data in accordance with embodiments of the invention.

Referring to FIG. 7, Jacobian regularization equations 700 include a definition of the square of the Frobenius norm of the Jacobian (top equation), which sums the squares of each element of the Jacobian, and a definition of a joint loss function evaluated for a batch of size B (bottom equation). The joint loss function includes a bare loss term and a Jacobian regularization term, which in this specific implementation, is proportional to average of the Frobenius norms of the Jacobian for the batch (the sum of the Frobenius norms divided by the batch size). The batch average of the Frobenius norm is multiplied by a factor, which in this case is a Jacobian regularization approximation coefficient (λ_{JR}) divided by two, but which may be defined in any convenient way.

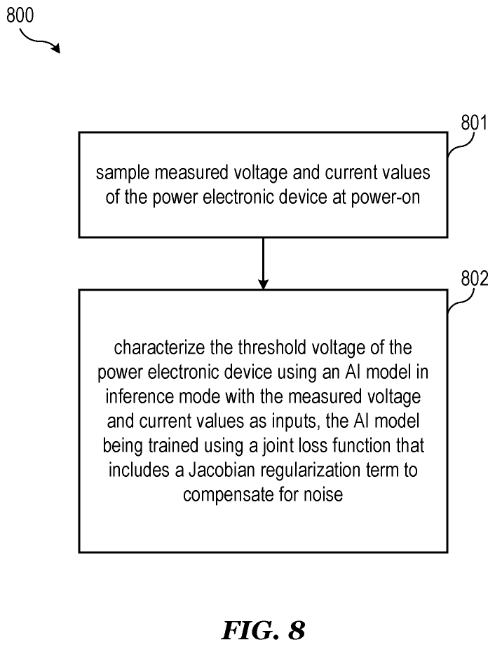

FIG. 8 illustrates an example method of characterizing threshold voltage of a power electronic device using an AI model in accordance with embodiments of the invention. The method of FIG. 8 may be combined with other methods and performed using the systems and apparatuses as described herein. For example, the method of FIG. 8 may be combined with any of the embodiments of FIGS. 1-7 and 9. Although shown in a logical order, the arrangement and numbering of the steps of FIG. 8 are not intended to be limited. The method steps of FIG. 8 may be performed in any suitable order or concurrently with one another as may be apparent to a person of skill in the art.

Referring to FIG. 8, a method 800 of characterizing threshold voltage of a power electronic device using an AI model includes a step 801 of sampling measured voltage and current values of the power electronic device at power-on. The threshold voltage of the power electronic device is characterized in a step 802 using the AI model in inference mode with the measured voltage and current values as inputs. The AI model is trained using a joint loss function that includes a Jacobian regularization term to compensate for noise. One or both of the step 801 and the step 802 may be performed by, by a microcontroller of the power electronic device.

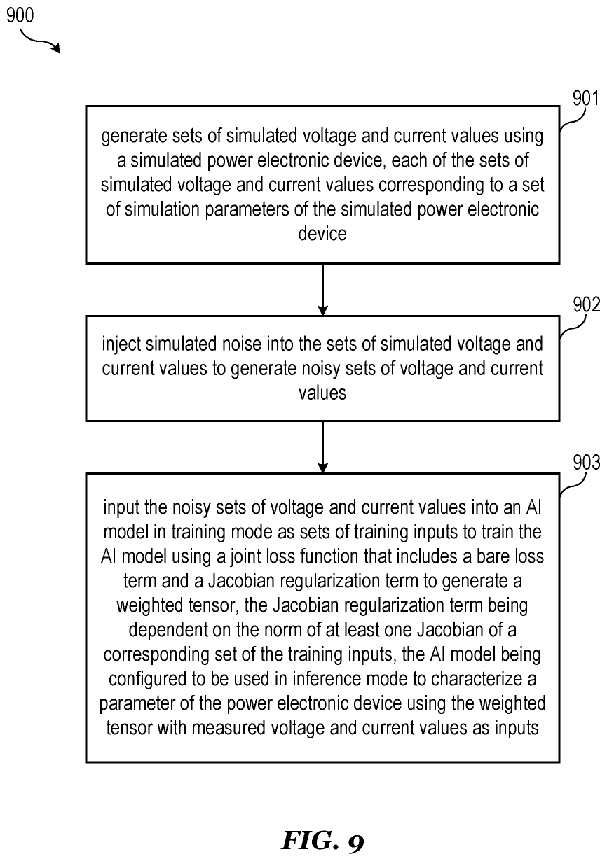

FIG. 9 illustrates an example method of training an AI model to characterize a parameter of a power electronic device in accordance with embodiments of the invention. The method of FIG. 9 may be combined with other methods and performed using the systems and apparatuses as described herein. For example, the method of FIG. 11 may be combined with any of the embodiments of FIGS. 1-8. Although shown in a logical order, the arrangement and numbering of the steps of FIG. 9 are not intended to be limited. The method steps of FIG. 9 may be performed in any suitable order or concurrently with one another as may be apparent to a person of skill in the art.

Referring to FIG. 9, a method 900 of training an AI model to characterize a parameter of a power electronic device using voltage and current measured during operation of the power electronic device includes a step 901 of generating sets of simulated voltage and current values using a simulated power electronic device. Each of the sets of simulated voltage and current values correspond to a set of simulation parameters of the simulated power electronic device. Step 902 includes injecting simulated noise into the sets of simulated voltage and current values to generate noisy sets of voltage and current values.

In a step 903, the noisy sets of voltage and current values are input into the AI model in training mode as sets of training inputs to train the AI model using a joint loss function comprising a bare loss term and a Jacobian regularization term to generate a weighted tensor. The Jacobian regularization term is dependent on the norm of at least one Jacobian of a corresponding set of the training inputs. The AI model is configured to be used in inference mode to characterize the parameter of the power electronic device using the weighted tensor with measured voltage and current values as inputs.

Example embodiments of the invention are summarized here. Other embodiments can also be understood from the entirety of the specification as well as the claims filed herein.

Example 1. A method of characterizing threshold voltage of a power electronic device using an artificial intelligence (AI) model, the method including: sampling, by a microcontroller of the power electronic device, measured voltage and current values of the power electronic device at power-on; and characterizing, by the microcontroller, the threshold voltage of the power electronic device using the AI model in inference mode with the measured voltage and current values as inputs, the AI model being trained using a joint loss function including a Jacobian regularization term to compensate for noise.

Example 2. The method of example 1, where the power electronic device is a power transistor including a gate, a source, and a drain, and the measured voltage and current values include the drain-source voltage and the drain current of the power transistor.

Example 3. The method of example 2, where the inputs include the gate-source voltage of the power transistor.

Example 4. The method of one of examples 1 to 3, where characterizing the threshold voltage of the power electronic device further includes outputting an estimated threshold voltage within about 100 ms of powering on the power electronic device.

Example 5. The method of one of examples 1 to 4, further including: characterizing drift of the threshold voltage of the power electronic device as a predictive marker of device degradation.

Example 6. The method of example 5, further including: rehabilitating the device degradation using new parameter values selected according to the characterization, the new parameter values including one or more of driving voltage, gate voltage, or source voltage.

Example 7. A method of training an artificial intelligence (AI) model to characterize a parameter of a power electronic device using voltage and current measured during operation of the power electronic device, the method including: generating sets of simulated voltage and current values using a simulated power electronic device, each of the sets of simulated voltage and current values corresponding to a set of simulation parameters of the simulated power electronic device; injecting simulated noise into the sets of simulated voltage and current values to generate noisy sets of voltage and current values; and inputting the noisy sets of voltage and current values into the AI model in training mode as sets of training inputs to train the AI model using a joint loss function including a bare loss term and a Jacobian regularization term to generate a weighted tensor, the Jacobian regularization term being dependent on the norm of at least one Jacobian of a corresponding set of the training inputs, the AI model being configured to be used in inference mode to characterize the parameter of the power electronic device using the weighted tensor with measured voltage and current values as inputs.

Example 8. The method of example 7, where the parameter of the power electronic device is threshold voltage of the power electronic device.

Example 9. The method of one of examples 7 and 8, where inputting the noisy sets of voltage and current values into the AI model includes repeating the steps of inputting a batch of the noisy sets of voltage and current values, processing the batch without updating internal parameters of the AI model, and updating the internal parameters of the AI model after processing the batch.

Example 10. The method of example 9, where the joint loss function is calculated for each batch by summing the norms of the Jacobian for each noisy set of voltage and current values of the batch and dividing by the batch size.

Example 11. The method of one of examples 7 to 10, where the bare loss term is a function of the training inputs, training outputs, and the parameter of the power electronic device, and the Jacobian regularization term is proportional to the summation of one or more functions of the norm of the Jacobian of a corresponding set of the training inputs, each of the one or more functions being the square of the Frobenius norm of the Jacobian.

Example 12. The method of one of examples 7 to 11, where the AI model in training mode performs a backpropagation training algorithm to generate the weighted tensor.

Example 13. The method of example 12, where the backpropagation training algorithm includes Levenberg-Marquardt backpropagation.

Example 14. A power electronics system including: a power electronic device; and a microcontroller including a processor and a non-transitory computer-readable memory storing a program that, when executed by the processor, causes the power electronics system to perform a method of characterizing a parameter of the power electronic device using an artificial intelligence (AI) model, the method including sampling measured voltage and current values of the power electronic device at power-on, and characterizing the parameter of the power electronic device using the AI model in inference mode with the measured voltage and current values as inputs, the AI model being trained using a joint loss function including a Jacobian regularization term to compensate for noise.

Example 15. The power electronics system of example 14, further including: an analog-to-digital converter (ADC) circuit coupled to the power electronic device, the ADC circuit being configured to receive analog voltage and current signals from the power electronic device, convert the analog voltage and current signals to voltage and current values, and output the voltage and current values to the processor.

Example 16. The power electronics system of example 15, where the microcontroller includes the ADC circuit.

Example 17. The power electronics system of one of examples 15 and 16, further including: a conditioning circuit coupled between the power electronic device and the ADC circuit, the conditioning circuit being configured to condition raw analog voltage and current signals to generate the analog voltage and current signals received by the ADC circuit.

Example 18. The power electronics system of example 17, where the conditioning circuit includes a plurality of operational amplifiers including inputs coupled to respective ones of the raw analog voltage and current signals, and outputs coupled to the ADC circuit.

Example 19. The power electronics system of one of examples 14 to 18, where the power electronic device is a power transistor including a gate, a source, and a drain, the parameter of the power electronic device is the threshold voltage of the power transistor, and the measured voltage and current values include the drain-source voltage and the drain current of the power transistor.

Example 20. The power electronics system of one of examples 14 to 19, where the power electronic device is a power silicon (Si) device or a power silicon carbide (SiC) device.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of characterizing threshold voltage of a power electronic device using an artificial intelligence (AI) model, the method comprising:
sampling, by a microcontroller of the power electronic device, measured voltage and current values of the power electronic device at power-on; and
characterizing, by the microcontroller, the threshold voltage of the power electronic device using the AI model in inference mode with the measured voltage and current values as inputs, the AI model being trained using a joint loss function comprising a Jacobian regularization term to compensate for noise.

2. The method of claim 1, wherein
the power electronic device is a power transistor comprising a gate, a source, and a drain,
and the measured voltage and current values comprise the drain-source voltage and the drain current of the power transistor.

3. The method of claim 2, wherein the inputs comprise the gate-source voltage of the power transistor.

4. The method of claim 1, wherein characterizing the threshold voltage of the power electronic device further comprises
outputting an estimated threshold voltage within about 100 ms of powering on the power electronic device.

5. The method of claim 1, further comprising:
characterizing drift of the threshold voltage of the power electronic device as a predictive marker of device degradation.

6. The method of claim 5, further comprising:
rehabilitating the device degradation using new parameter values selected according to the characterization, the new parameter values comprising one or more of driving voltage, gate voltage, or source voltage.

7. A method of training an artificial intelligence (AI) model to characterize a parameter of a power electronic device using voltage and current measured during operation of the power electronic device, the method comprising:
generating sets of simulated voltage and current values using a simulated power electronic device, each of the sets of simulated voltage and current values corresponding to a set of simulation parameters of the simulated power electronic device;
injecting simulated noise into the sets of simulated voltage and current values to generate noisy sets of voltage and current values; and
inputting the noisy sets of voltage and current values into the AI model in training mode as sets of training inputs to train the AI model using a joint loss function comprising a bare loss term and a Jacobian regularization term to generate a weighted tensor, the Jacobian regularization term being dependent on the norm of at least one Jacobian of a corresponding set of the training inputs, the AI model being configured to be used in inference mode to characterize the parameter of the power electronic device using the weighted tensor with measured voltage and current values as inputs.

8. The method of claim 7, wherein the parameter of the power electronic device is threshold voltage of the power electronic device.

9. The method of claim 7, wherein inputting the noisy sets of voltage and current values into the AI model comprises repeating the steps of
inputting a batch of the noisy sets of voltage and current values,
processing the batch without updating internal parameters of the AI model, and
updating the internal parameters of the AI model after processing the batch.

10. The method of claim 9, wherein the joint loss function is calculated for each batch by summing the norms of the Jacobian for each noisy set of voltage and current values of the batch and dividing by the batch size.

11. The method of claim 7, wherein
the bare loss term is a function of the training inputs, training outputs, and the parameter of the power electronic device, and
the Jacobian regularization term is proportional to the summation of one or more functions of the norm of the Jacobian of a corresponding set of the training inputs, each of the one or more functions being the square of the Frobenius norm of the Jacobian.

12. The method of claim 7, wherein the AI model in training mode performs a backpropagation training algorithm to generate the weighted tensor.

13. The method of claim 12, wherein the backpropagation training algorithm comprises Levenberg-Marquardt backpropagation.

14. A power electronics system comprising:
a power electronic device; and
a microcontroller comprising a processor and a non-transitory computer-readable memory storing a program that, when executed by the processor, causes the power electronics system to perform a method of characterizing a parameter of the power electronic device using an artificial intelligence (AI) model, the method comprising
sampling measured voltage and current values of the power electronic device at power-on, and
characterizing the parameter of the power electronic device using the AI model in inference mode with the measured voltage and current values as inputs, the AI model being trained using a joint loss function comprising a Jacobian regularization term to compensate for noise.

15. The power electronics system of claim 14, further comprising:
an analog-to-digital converter (ADC) circuit coupled to the power electronic device, the ADC circuit being configured to
receive analog voltage and current signals from the power electronic device,
convert the analog voltage and current signals to voltage and current values, and
output the voltage and current values to the processor.

16. The power electronics system of claim 15, wherein the microcontroller comprises the ADC circuit.

17. The power electronics system of claim 15, further comprising:
a conditioning circuit coupled between the power electronic device and the ADC circuit, the conditioning circuit being configured to condition raw analog voltage and current signals to generate the analog voltage and current signals received by the ADC circuit.

18. The power electronics system of claim 17, wherein the conditioning circuit comprises a plurality of operational amplifiers comprising inputs coupled to respective ones of the raw analog voltage and current signals, and outputs coupled to the ADC circuit.

19. The power electronics system of claim 14, wherein
the power electronic device is a power transistor comprising a gate, a source, and a drain,
the parameter of the power electronic device is the threshold voltage of the power transistor, and
the measured voltage and current values comprise the drain-source voltage and the drain current of the power transistor.

20. The power electronics system of claim 14, wherein the power electronic device is a power silicon (Si) device or a power silicon carbide (SiC) device.
